(19) United States
(12) Patent Application Publication
(10) Pub. No.: US 2004/0245433 A1
(43) Pub. Date: Dec. 9, 2004

(54) Solid-state imaging device and method for driving the same

(76) Inventor: Eiji Koyama, Kyoto (JP)

Correspondence Address: Edwards & Angell, LLP, P.O. Box 55874, Boston, MA, 02205, US

(21) Appl. No.: 10/851,458

(22) Filed: May 21, 2004

(30) Foreign Application Priority Data
May 21, 2003 (JP) 2003-144126

(51) Int. Cl. H01L 27/00

(52) U.S. Cl. 250/208.1

(57) ABSTRACT

A solid-state imaging device includes at least one pixel block. The at least one pixel block includes a plurality of light receiving sections for generating charges by opto-electric conversion of incident light; an optical signal detection section, provided commonly to the plurality of light receiving sections, for outputting a signal in accordance with the amount of charges generated by each of the plurality of light receiving sections; and a charge transfer control section for controlling a flow of the generated charges to the optical signal detection section.

This non-provisional application claims priority under 35 U.S.C., S119(a), on Patent Application No. 2003-144126 filed in Japan on May 21, 2003, the entire contents of which are hereby incorporated by reference.

### BACKGROUND OF THE INVENTION

1. Field of the Invention

The present invention relates to a solid-state imaging device using a threshold voltage modulation-system MOS-type image sensor or the like, which is usable for an image input device such as a video camera, an electronic camera, an image input camera, a scanner, a facsimile device or the like; and a method for driving the same.

2. Description of the Related Art

Conventionally, a semiconductor image sensor such as, for example, a CCD-type image sensor or a MOS-type image sensor is used for most image input devices. Recently, a MOS-type image sensor again has been attracting attention for the advantages of consuming loss power than a CCD-type image sensor and the ability to be produced with a CMOS technique which is also used for producing peripheral circuits.

As an example of such a MOS-type image sensor of a threshold voltage modulation system, Japanese Patent No. 2935492 discloses a solid-state imaging device including a carrier pocket region (a high concentration buried layer) acting as a charge accumulation region below a channel region of a MOS translator for detecting optical signals.

With reference to FIGS. 8 and 9, the conventional MOS-type image sensor of a threshold voltage modulation system disclosed in Japanese Patent No. 2935492 will be described.

FIG. 8 is a plan view of one unit pixel area 10 of the conventional MOS-type image sensor, and FIG. 9 is a cross-sectional view of the MOS-type image sensor shown in FIG. 8 taken along line A-A in FIG. 8.

The MOS-type image sensor includes a plurality of unit pixel areas 10 arranged in a matrix, for example, in rows and columns.

The pixel area 10 shown in FIGS. 8 and 9 will be described as an example of the plurality of pixel areas 10. As shown in FIGS. 8 and 9, the pixel area 10 includes a light receiving diode 11 for receiving light and generating charges corresponding to the amount of received light by opto-electric conversion, and an optical signal detection MOS transistor 12 provided adjacent to the light receiving diode 11 for detecting the charges generated by the light receiving diode 11 as a signal.

On a P-type substrate 14, an N-type well region 16 is provided for each pixel area 10. A P-type well region 18 is provided in an upper portion of the N-type well region 16. Namely, the N-type well region 16 is provided so as to surround the P-type well region 18.

The N-type well region 16 is connected to an N-type drain region 17. In a sweep-out period, signal charges accumulated in a hole pocket region 22 are swept out from the hole pocket region 22 over the N-type well region 16 toward the substrate 14, by a gate voltage applied to a gate electrode 23.

A P⁺-type channel stop region 15 is provided below the N-type well region 16 and between two adjacent pixel areas 10. The N-type well region 16 is divided into a plurality of pixel areas each corresponding to one pixel area 10 by the P⁺-type channel stop region 15 and the P-type substrate 14. Thus, the plurality of pixel areas are formed.

The light receiving diode 11 and the optical signal detection MOS transistor 12 share the same P-type well region 18, and are connected to each other via the P-type well region 18.

The light receiving diode 11 includes the N-type well region 16 provided on the P-type substrate 14 and the P-type well region 18 in a floating state provided on the N-type well region 16. The light receiving diode 11 shares the drain region 17 as an N-type region with the optical signal detection MOS transistor 12. The P-type well region 18 acts as a light receiving region. When the P-type well region 18 is illuminated with light, signal charges are generated. Electrons or holes can be generated as signal charges. In this case, holes are generated.

The optical signal detection MOS transistor 12 includes the N-type drain region 17, an N-type source region 21, the P-type hole pocket region 22 having a ring shape when seen from above, the gate electrode 23 having a ring shape when seen from above, and a channel region 24 in which a current carrier is transferred.

The N-type drain region 17 is provided on a surface of the P-type well region 18 so as to surround the ring-shaped gate electrode 23. The N-type drain region 17 also has a ring shape when seen from above and acts as an N⁺-type diffusion layer.

The N-type source region 21 is provided on the surface of the P-type well region 18 inside the ring-shaped gate electrode 23. The N-type source region 21 also acts as an N⁺-type diffusion layer.

The P-type hole pocket region 22 is formed at a position which is in the P-type well region 18, below the gate electrode 23 and in the vicinity of the N-type source region 21. The P-type hole pocket region 22 is provided so as to surround the source region 21. When seen from above, the P-type hole pocket region 22 is ring-shaped and acts as a P⁺-type diffusion layer.

In the P-type hole pocket region 22, an optical signal (charges) generated by the light receiving diode 11 is accumulated via the P-type well region 18. When the pixel area 10 is selected by a gate voltage applied to the gate electrode 23 in an S read period (signal read period), a signal corresponding to the level of the optical signal (the amount of the signal charges) in the P-type hole pocket region 22 is output from the N-type drain region 17.

The channel region 24 is located at a position between the N-type source region 21 and the N-type drain region 17, on a surface of the P-type well region 18 and below the gate electrode 23. The channel region 24 is an N-type layer.

The gate electrode 23 is a signal detection gate, and is provided on the P-type well region 18 with a gate insulating layer (not shown) interposed therebetween. The gate electrode 23 is ring-shaped when seen from above.

The MOS-type image sensor includes a plurality of unit pixel areas 10 each having the above-described structure arranged in a matrix in rows and columns (two-dimensionally). A driving circuit (for controlling a gate voltage, a drain voltage, and a source voltage) separately controls the voltage of a selected line and the voltage of a non-selected line. Thus, an image signal is sequentially read from the unit pixel area 10 which corresponds to the selected row and the selected column among the plurality of unit pixel areas 10.

With reference to FIG. 10, a basic operation of the conventional MOS-type image sensor having the above-described structure will be described.

FIG. 10 is a timing diagram illustrating signal waveforms regarding an operation of the MOS-type image sensor shown in FIGS. 8 and 9.

As shown in FIG. 10, in the MOS-type image sensor, a series of operations including a charge accumulation operation, a signal read operation, a sweep-out operation (initialization), and a noise read operation are performed repeatedly.

(Accumulation Period)

In an accumulation period, the drain region 17 and the source region 21 of the optical signal detection MOS transistor 12 are each supplied with a voltage of 1 V, and the gate electrode 23 of the optical signal detection MOS transistor 12 is supplied with a voltage of about 3 V. In this period, holes as optical signal carriers or signal charges are generated in the P-type well region 18 in an electrically floating state by the light receiving diode 11 being illuminated with light. Since the hole pocket region 22, which is in the vicinity of the source region 21, is a high impurity concentration region, the signal charges generated in the light receiving diode 11 are transferred to, and accumulated in, the P-type hole pocket region 22 by an electric field formed by a P-type concentration gradient.

In the accumulation period, the optical signal detection MOS transistor 12 is ON, and the drain region 17 and the source region 21 are completely conducting to each other. Therefore, an area immediately below the gate electrode 23 is filled with electrons. Accordingly, an area immediately below the drain region 17, the source region 21 and the gate electrode 23 is entirely filled with electrons, which suppresses the generation of a dark current component at an interface of each transistor.

(S Read Period)

In an S read period (signal read period), the optical signal detection MOS transistor 12 operates as follows. The source region 21 is connected to a constant current source. A source follower circuit is formed including the drain region 17, the source region 21 and the gate electrode 23. The drain region 17 is supplied with a voltage of 3 V, and the gate electrode 23 is supplied with a voltage of about 2 V. With such settings, the optical signal detection MOS transistor 12 is operated in a saturated state. Thus, the potential of the source region 21 is changed in accordance with the amount of charges accumulated in the hole pocket region 22, and is read as a signal (signal S).

(Sweep-Out Period)

Next in a sweep-out period, the drain region 17, the source region 21 and the gate electrode 23 are each supplied with a high voltage of about 5 to 7 V. Thus, all the signal charges accumulated in the hole pocket region 22 are discharged toward the P-type substrate 14 over the N-type well region 16.

(N Read Period)

In an N read period (noise read period), the optical signal detection MOS transistor 12 operates as follows. The source region 21 is again connected to a constant current source. A source follower circuit is formed including the drain region 17, the source region 21 and the gate electrode 23. The drain region 17 is supplied with a voltage of 3 V, and the gate electrode 23 is supplied with a voltage of about 2 V. With such settings, the optical signal detection MOS transistor 12 is operated in a saturated state. Thus, a signal in the state where the hole pocket region 22 has no charges (signal) accumulated therein is read as a noise.

A difference between the signal S which is read in the S read period and the noise (signal N) which is read in the N read period is output through a differential amplification circuit, a clamp circuit or the like as an image signal for each pixel area 10. In this manner, the influence of variance of offsets of the optical signal detection MOS transistors 12 of the pixel areas 10 is reduced.

The conventional MOS-type image sensor described above, in which each unit pixel area 10 includes one light receiving diode 11 and one optical signal detection MOS transistor 12, has the following problems.

In the optical signal detection MOS transistor 12, the gate electrode 23 has a ring shape when seen from above, and the hole pocket region 22 having a ring shape when seen from above is provided below the gate electrode 23. The hole pocket region 22 is a high concentration P⁺-type diffusion layer. The threshold voltage of the optical signal detection MOS transistor 12 is changed in accordance with the amount of signal charges accumulated in the hole pocket region 22. In order to read noise (signal N) after the S read period and the sweep-out period, it is necessary to completely deplete the high concentration hole pocket region 22 during the sweep-out period.

The optical signal detection MOS transistor 12 for performing such a special operation is required to have a larger area than a transistor produced by a usual CMOS process. This type of MOS transistor cannot be easily reduced in size in accordance with the size reduction in the CMOS technique.

Accordingly, the area occupied by the optical signal detection MOS transistor 12 in the unit pixel area 10 increases, which decreases the area of the light receiving diode 11. As a result, the sensitivity of the MOS-type image sensor is decreased.

As shown in FIG. 8, the light receiving diode 11 is adjacent on one side of the optical signal detection MOS transistor 12. In such a structure, the potential profile below the ring-shaped gate electrode 23 becomes easily imbalanced between the side where the light receiving diode 11 is provided and the other side. As a result, the linearity between the optical signal (signal charges) generated in the light receiving diode 11 and the output signal from the optical signal detection MOS transistor 12 may be undesirably spoiled.

In the sweep-out period, it is necessary to completely sweep out the optical signal (signal charges) from the hole pocket region 22 toward the P-type substrate 14. Therefore, the drain region 17, the source region 21 and the gate electrode 23 of the optical signal detection MOS transistor 12 each need to be supplied with a high voltage of 5 V to 7 V.

### SUMMARY OF THE INVENTION

According to one aspect of the invention, a solid-state imaging device includes at least one pixel block. The at least one pixel block includes a plurality of light receiving sections for generating charges by opto-electric conversion of incident light; an optical signal detection section, provided commonly to the plurality of light receiving sections, for outputting a signal in accordance with the amount of charges generated by each of the plurality of light receiving sections; and a charge transfer control section for controlling a flow of the generated charges to the optical signal detection section.

In one embodiment of the invention, the optical signal detection section is surrounded by the plurality of light receiving sections.

In one embodiment of the invention, the optical signal detection section is located at the center of each of the plurality of light receiving sections.

In one embodiment of the invention, the charge transfer control section includes a plurality of transistors respectively provided between the optical signal detection section and the plurality of light receiving sections.

In one embodiment of the invention, each of the plurality of light receiving sections is a light receiving diode. The optical signal detection section is an optical signal detection transistor including a charge accumulation region for accumulating the charges generated by each of the plurality of light receiving sections.

In one embodiment of the invention, each of the plurality of light receiving sections includes a first conductivity type well region; and a second conductivity type impurity diffusion region provided on the first conductivity type well region.

In one embodiment of the invention, the optical signal detection section further includes a second conductivity type drain region, a second conductivity type source region, a gate electrode, and a channel region. The charge accumulation region is provided in a first conductivity type first well region. The charge accumulation region is located closer to the second conductivity type source region than to the second conductivity type drain region. The charge accumulation region has an impurity concentration which is higher than the impurity concentration of the first conductivity type first well region.

In one embodiment of the invention, the gate electrode ls ring-shaped. The second conductivity type ource region is surrounded by the gate electrode. The gate electrode is surrounded by the second conductivity type drain region. The charge accumulation region is ring-shaped and is provided so as to surround the second conductivity type source region.

In one embodiment of the invention, each of the plurality of light receiving sections includes a first conductivity type second well region; and a second conductivity type impurity diffusion region provided on the first conductivity type second well region. The second conductivity type drain region is formed integrally with the second conductivity type impurity diffusion region.

In one embodiment of the invention, the solid-state imaging device includes a plurality of pixel blocks, and the second conductivity type drain region is shared by the plurality of pixel blocks.

According to another aspect of the invention, a method for driving a solid-state imaging device is provided. The solid-state imaging device includes at least one pixel block. The at least one pixel block includes a plurality of light receiving sections for generating charges by opto-electric conversion of incident light; an optical signal detection section, provided commonly to the plurality of light receiving sections, for outputting a signal in accordance with the amount of charges generated by each of the plurality of light receiving sections; and a charge transfer control section for controlling a flow of the generated charges to the optical signal detection section. The optical signal detection section includes a charge accumulation region for accumulating the charges generated by each of the plurality of light receiving sections, a drain region, a source region, a gate electrode, and a channel region. The method includes a sweep-out step of sweeping out charges accumulated in the charge accumulation region; a first reading step of reading a potential of the source region after the sweep-out step is performed; a transfer step of selecting one of the plurality of light receiving sections and transferring the charges generated by the selected light receiving section to the charge accumulation region; and a second reading stop of reading a potential of the source region in accordance with the charges accumulated in the amount of charge accumulation region.

In one embodiment of the invention, the method further includes the step of outputting an image signal indicating a difference between the potential which is read in the first reading step and the potential which is read in the second reading step.

In one embodiment of the invention, the sweep-out step, the first reading step, the transfer step and the second reading step are performed for each of the plurality of light receiving sections.

In one embodiment of the invention, the plurality of light receiving sections include a first light receiving section and a second light receiving section. The transfer step when the second light receiving section is selected is performed after the second reading step performed when the first light receiving section is selected.

In one embodiment of the invention, the method further includes the step of outputting an image signal indicating a difference between the potential, which is read in the second reading step performed when the first light receiving section is selected, and the potential, which is read in the second reading step performed when the second light receiving section is selected.

In one embodiment of the invention, in the sweep-out step, the charge accumulation region is not completely depleted.

A solid-state imaging device according to the present invention includes an optical signal detection section, provided commonly to the plurality of light receiving sections, for outputting a signal in accordance with the amount of charges generated by each of the plurality of light receiving sections. Owing to such a structure, the area occupied by the optical signal detection transistor in a pixel block is significantly reduced, and thus the area occupied by the light receiving section is significantly enlarged. Thus, the light detection sensitivity can be improved.

A solid-state imaging device according to the present invention further includes a charge transfer control section for controlling a flow of the generated charge to the optical signal detection section. Owing to such a structure, the signal in accordance with the charge generated in each of the plurality of light receiving sections can be independently read.

The optical signal detection section is located at the center of the plurality of light receiving sections. Owing to such a structure, the potential profile below the gate electrode is unlikely be imbalanced.

In a solid-state imaging device according to the present invention, the flow of charges to the optical signal detection section is controlled by the charge transfer control section. Therefore, even in a sweep-out period, the charges accumulated in the charge accumulation region can be retained. Thus, the drain region may be shared by the plurality of pixels. (Namely, the drain regions of the plurality of pixel blocks may be integrally formed.) This further enlarges the area occupied by the light receiving sections and improves the light detection sensitivity.

A method for driving a solid-state imaging device according to the present invention includes a sweep-out stop of sweeping out the charges accumulated in the charge accumulation region; a first reading step of reading a potential of the source region after the sweep-out step is performed; a transfer step of selecting one of the plurality of light receiving sections and transferring the charges generated by the selected light receiving section to the charge accumulation region; and a second reading step of reading a potential of the source region in accordance with the amount of charges accumulated in the charge accumulation region. By performing these steps for each of the plurality of light receiving sections, a signal can be read from the pixel sections. In this case, an image signal, indicating a difference between the potential which is read in the first reading step and the potential which is read in the second reading step, is generated and output by the solid-state imaging device.

After the second reading stop performed when the first light receiving section is selected, the transfer step when the second light receiving section is selected is performed. In this case, an image signal, indicating a difference between the potential which is read in the second reading step performed when the first light receiving section is selected and the potential which is read in the second reading step performed when the second light receiving section is selected, is generated and output by the solid-state imaging device. Since the number of times that the first reading step is performed is reduced, the operating speed of the sweep-out step, the transfer step and the second reading step can be reduced.

In addition, an image signal is generated so as to indicate a difference between a potential which is read in a prescribed step and a potential which is read in another prescribed step. Therefore, the charge accumulation region does not need to be completely depleted, but may be depleted sufficiently to accumulate additional charges. This allows the voltage applied to the optical signal detection section in the sweep-out period to be set lower.

Thus, the invention described herein makes possible the advantages of providing a solid-state imaging device having a larger area occupied by the light receiving diode to improve the sensitivity, guaranteeing the linearity between the signal output and the optical signal generated by the light receiving diode, and reducing each driving voltage required in a sweep-out period; and a method for driving the same.

These and other advantages of the present invention will become apparent to those skilled in the art upon reading and understanding the following detailed description with reference to the accompanying figures.

### BRIEF DESCRIPTION OF THE DRAWINGS

FIG. 1 shows a MOS-type image sensor as a solid-state imaging device according to a first example of the present invention;

FIG. 2 is a cross-sectional view of the MOS-type image sensor shown in FIG. 1 taken along line B-B in FIG. 1;

FIG. 3 is a timing diagram illustrating signal waveforms regarding an operation of the MOS-type image sensor shown in FIG. 1;

FIG. 4 shows a MOS-type image sensor as a solid-state imaging device according to a second example of the present invention;

FIG. 5 is a timing diagram illustrating signal waveforms regarding an operation of the MOS-type image sensor shown in FIG. 4;

FIG. 6 is a timing diagram illustrating signal waveforms regarding an operation of a MOS-type image sensor according to a third example of the present invention;

FIG. 7 shows a MOS-type image sensor as a solid-state imaging device according to a fourth example of the present invention;

FIG. 8 is a plan view of one unit pixel area of a conventional MOS-type image sensor;

FIG. 9 is a cross-sectional view of the MOS-type image sensor shown in FIG. 8 taken along line A-A in FIG. 8; and

FIG. 10 is a timing diagram illustrating signal waveforms regarding an operation of the conventional MOS-type image sensor shown in FIGS. 8 and 9.

### DESCRIPTION OF THE PREFERRED EMBODIMENTS

Hereinafter, the present invention will be described by way of illustrative examples with reference to the accompanying drawings.

In first through fourth examples, a solid-state imaging device according to the present invention is realized as a MOS-type image sensor.

### EXAMPLE 1

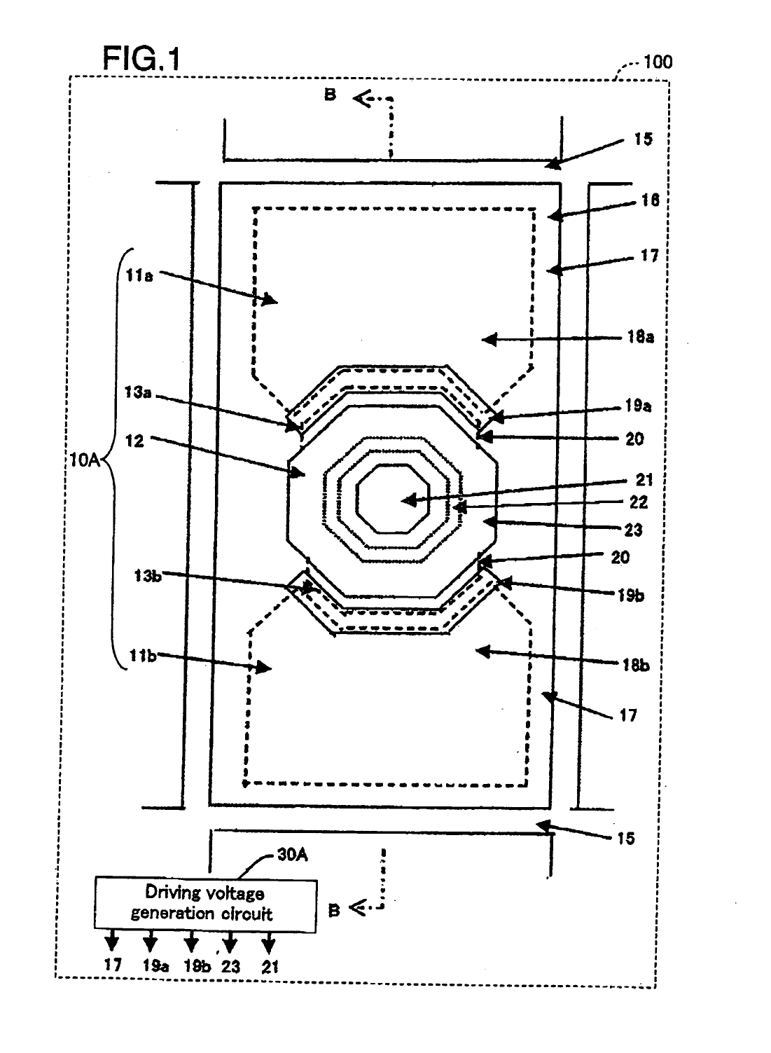

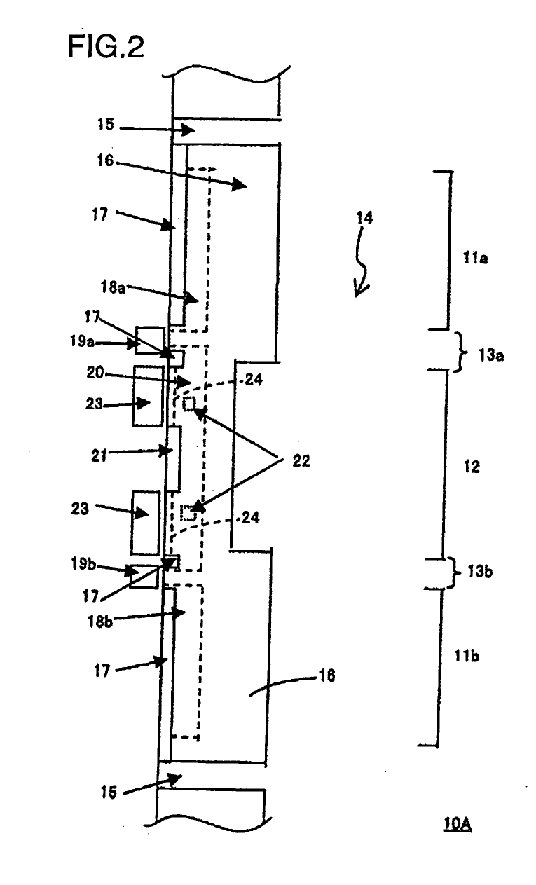

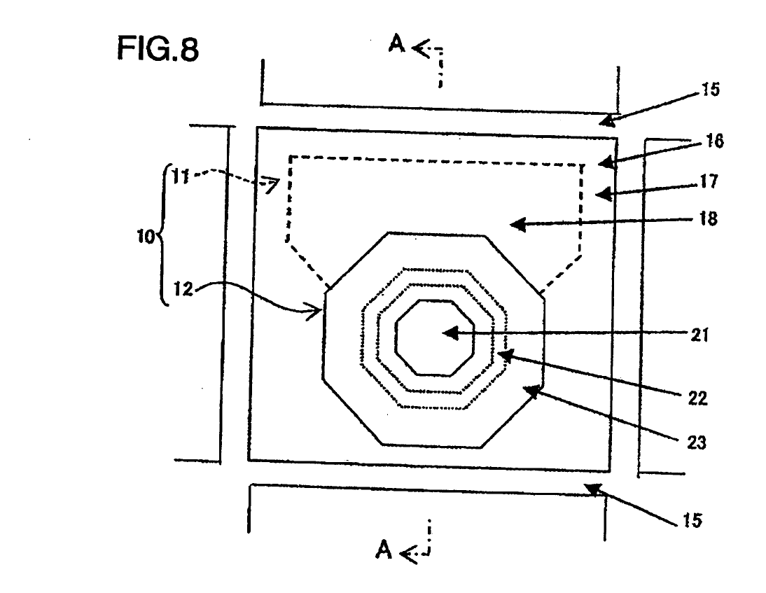

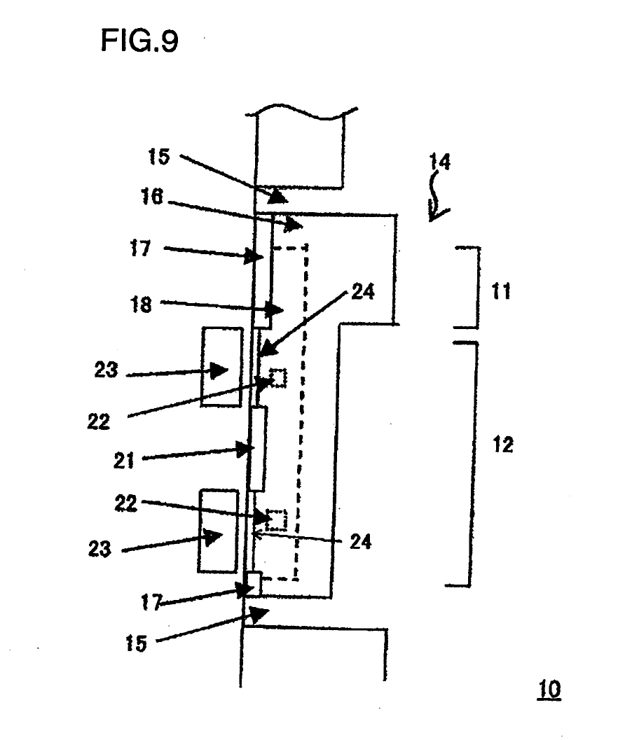

FIG. 1 shows a solid-state imaging device 100 according to the first example of the present invention. The solid-state imaging device 100 includes at least one pixel block 10A and a driving voltage generation circuit 30A. In this example, the solid-state imaging device 100 is a MOS-type image sensor including a plurality of pixel blocks 10A. FIG. 2 is a cross-sectional view of the solid-state imaging device 100 shown in FIG. 1 taken along line B-B in FIG. 1. Identical elements as described above with reference to FIGS. 8 and 9 bear identical reference numerals thereto and a detailed description thereof will be omitted.

Each of the pixel blocks 10A includes a plurality of light receiving sections for generating charges by opto-electric conversion of incident light, and an optical signal detection section, provided commonly to the plurality of light receiving sections, for outputting a signal in accordance with the amount of charges generated by each of the plurality of light receiving sections.

As shown in FIGS. 1 and 2, the pixel block 10A includes a first pixel portion (shown in an upper part of FIGS. 1 and 2) and a second pixel portion (shown in a lower part of FIGS. 1 and 2). The first pixel portion includes a light receiving diode 11a (a light receiving section) for receiving light and generating charges corresponding to the amount of received light by opto-electric conversion; an optical signal detection MOS transistor 12 (an optical signal detection section) including a charge accumulation region for accumulating the signal charges generated by the light receiving diode 11a and allowing a signal, corresponding to the amount of the signal charges accumulated in the charge accumulation region, to be readable therefrom; and an optical signal transfer MOS transistor 13a (a first optical signal transfer control section) for controlling a flow of the signal charges from the light receiving diode 11a toward the charge accumulation region of the optical signal detection MOS transistor 12. Similarly, the second pixel portion includes a light receiving diode 11b (a light receiving section), the optical signal detection MOS transistor 12 which is shared with the first pixel portion, and an optical signal transfer MOS transistor 13b (a second optical signal transfer control section) for controlling a flow of the signal charges from the light receiving diode 11b toward the charge accumulation region of the optical signal detection MOS transistor 12. A charge transfer control section includes the first optical signal transfer control section and the second optical signal transfer control section.

As described above, the optical signal detection MOS transistor 12 is shared by the first and second pixel portions (or used by the two light receiving diodes 11a and 11b), and is located at a center of the pixel block 10A between the light receiving diodes 11a and 11b. The optical signal transfer MOS transistor 13a is located between the light receiving diode 11a and the optical signal detection MOS transistor 12, and the optical signal transfer MOS transistor 13b is located between the light receiving diode 11b and the optical signal detection MOS transistor 12.

On a P-type substrate 14, an N-type well region 16 is provided for each pixel block 10A. A P-type well region 18a and a P-type well region 18b (second well region) both in a floating state are provided in an upper portion of the N-type well region 16. The P-type well region 18a and the P-type well region 18b each act as a light receiving region. When the P-type well region 18a and the P-type well region 18b are illuminated with light, signal charges (holes in this case) are generated. An N-type drain region 17 is provided as an N⁺-type impurity diffusion region on a surface of the P-type well regions 18a and 18b. The light receiving diode 11a includes an N⁺-type impurity diffusion region and a P-type well region 18a. The light receiving diode 11b includes an N⁺-type impurity diffusion region and a P-type well region 18b.

The optical signal detection MOS transistor 12 is provided in a P-type well region 20 (a first well region) provided in the N-type well region 16. The P-type well region 20 is independently provided from the P-type well regions 18a and 18b. The optical signal detection MOS translator 12 includes the N-type drain region 17, an N-type source region 21, a gate electrode 23 having a ring shape when seen from above, a channel region 24, and a hole pocket region 22 acting as a signal charge accumulation region. The hole pocket region 22 has a ring shape when seen from above.

The N-type drain region 17 is provided on a surface of the P-type well region 20 as an N⁺-type diffusion layer integral with impurity diffusion regions of the light receiving diodes 11a and 11b.

The N-type source region 21 is provided on the surface of the P-type well region 20 inside the ring-shaped gate electrode 23 (a detection gate). The N-type source region 21 is a prescribed distance away from the drain region 17 and acts as an N⁺-type diffusion layer.

The gate electrode 23 is provided on the P-type well region 20 with a gate insulating layer (not shown) interposed therebetween. The gate electrode 23 is located between the drain region 17 and the source region 21. The gate electrode 23 has a ring shape when seen from above. The source region 21 is surrounded by the gate electrode 23, and the gate electrode 23 is surrounded by the drain region 17.

The channel region 24 is provided at a position on the surface of the P-type well region 20 and below the gate electrode 23. The channel region 24 acts as an N-type impurity layer in which electron carriers are transferred.

The P-type hole pocket region 22 is a signal charge accumulation region, and is provided at a position which is in the P-type well region 20, below the channel region 24 and closer to the source region 21 than to the drain region 17. The P-type hole pocket region 22 is provided so as to surround the source region 21. The P-type hole pocket region 22 acts as a P⁺-type high concentration buried diffusion layer having a higher impurity concentration than that of the P-type well region 20.

The optical signal transfer MOS transistor 13a shares a part of the drain region 17 located in the light receiving diode 11a as an N-type drain region with the light receiving diode 11a, and shares a part of the drain region 17 located in the optical signal detection MOS transistor 12 as an N-type source region with the optical signal detection MOS transistor 12. The optical signal transfer MOS transistor 13a further includes a gate electrode (transfer gate) 19a provided on the P-type well region 18a, the N-type well region 16 and the P-type well region 20 with a gate insulating layer (not shown) interposed therebetween.

The optical signal transfer MOS transistor 13b shares a part of the drain region 17 located in the light receiving diode 11b as an N-type drain region with the light receiving diode 11b, and shares a part of the drain region 17 located in the optical signal detection MOS transistor 12 as an N-type source region with the optical signal detection MOS transistor 12. The optical signal transfer MOS transistor 13b further includes a gate electrode (transfer gate) 19b provided on the P-type well region 18b, the N-type well region 16 and the P-type well region 20 with a gate insulating layer (not shown) interposed therebetween.

The N-type well region 16 is divided into a plurality of areas, each corresponding to one pixel block 10A. The N-type well region 16 is divided by the P-type substrate 14 below the N-type well region 16 and the P⁺-type channel stop region 15.

The MOS-type image sensor 100 includes a plurality of unit pixel blocks 10A each having the above-described structure arranged in a matrix in rows and columns (two-dimensionally). By controlling a voltage applied to each of the gate electrodes (transfer gates) 19a and 19b by a gate driving circuit (not shown), an optical signal (signal charges) generated by the light receiving diode 11a is sequentially transferred to the hole pocket region 22 from the P-type well region 18a via the optical signal transfer MOS transistor 13a and the P-type well region 20, or an optical signal (signal charges) generated by the light receiving diode 11b is sequentially transferred to the hole pocket region 22 from the P-type well region 18b via the optical signal transfer MOS translator 13b and the P-type well region 20.

By controlling a gate voltage applied to the gate electrode (detection gate) 23 in an S read period (signal read period), a signal in accordance with the amount of charges accumulated in the hole pocket region 22 is output from the source region 21, and sequentially read as an image signal of a selected pixel block.

The N-type well region 16 provided so as to surround the P-type well regions 18a, 18b and 20 is connected to the drain region 17. The signal charges accumulated in the hole pocket region 22 are swept out from the hole pocket region 22 over the N-type well region 16 toward the P-type substrate 14 by a gate voltage applied to the gate electrode 23 in a sweep-out period.

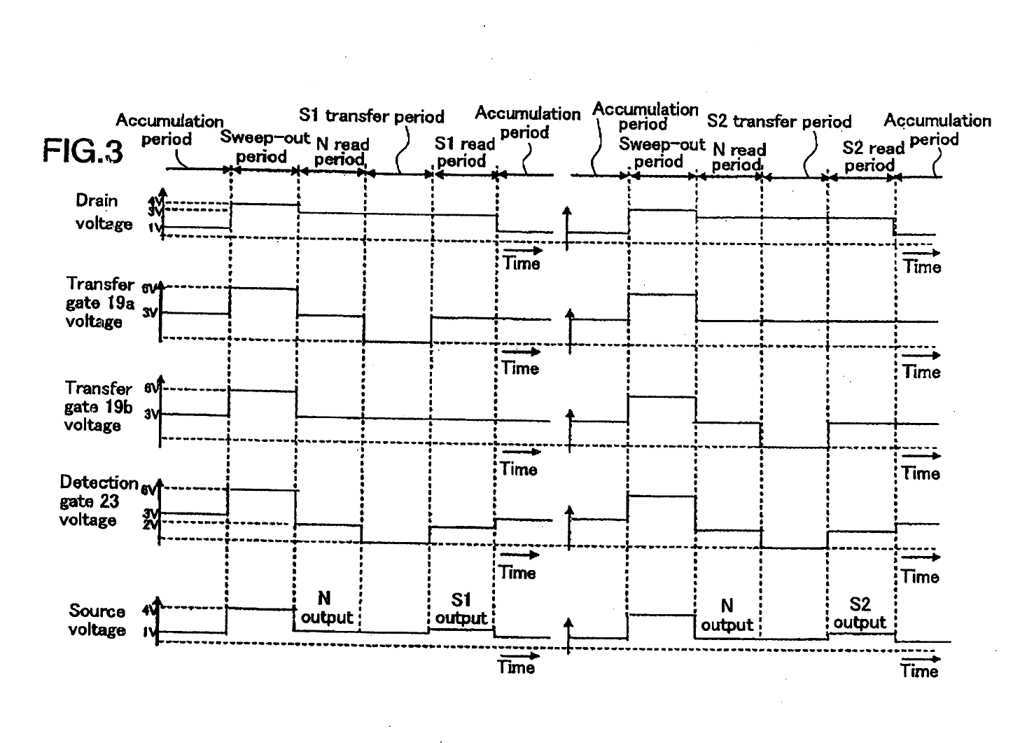

The MOS-image sensor 100 shown in FIG. 1 includes a driving voltage generation circuit 30A for controlling an imaging operation of the pixel block 10. The driving voltage generation circuit 30A outputs driving voltages as shown in FIG. 3 to the drain region 17, the transfer gates 19a and 19b, the detection gate 23, and the source region 21 at a prescribed timing.

A method for driving the MOS-type image sensor (solid-state imaging device) 100 in the first example of the present invention will be described with reference to FIG. 3.

FIG. 3 is a timing diagram illustrating signal waveforms regarding an operation of the MOS-type image sensor 100 shown in FIG. 1. FIG. 3 shows the signal waveforms in the drain region 17, the transfer gates 19a and 19b, the detection gate 23 and the source region 21.

In the MOS-type image sensor 100 shown in FIG. 1, a series of operations including a charge accumulation operation, a sweep-out operation (initialization), an N (noise) read operation, a signal (S) transfer operation, and a signal (S) read operation are performed repeatedly.

An operation of the first pixel portion shown in the upper portion of FIGS. 1 and 2 will be described.

(Accumulation Period)

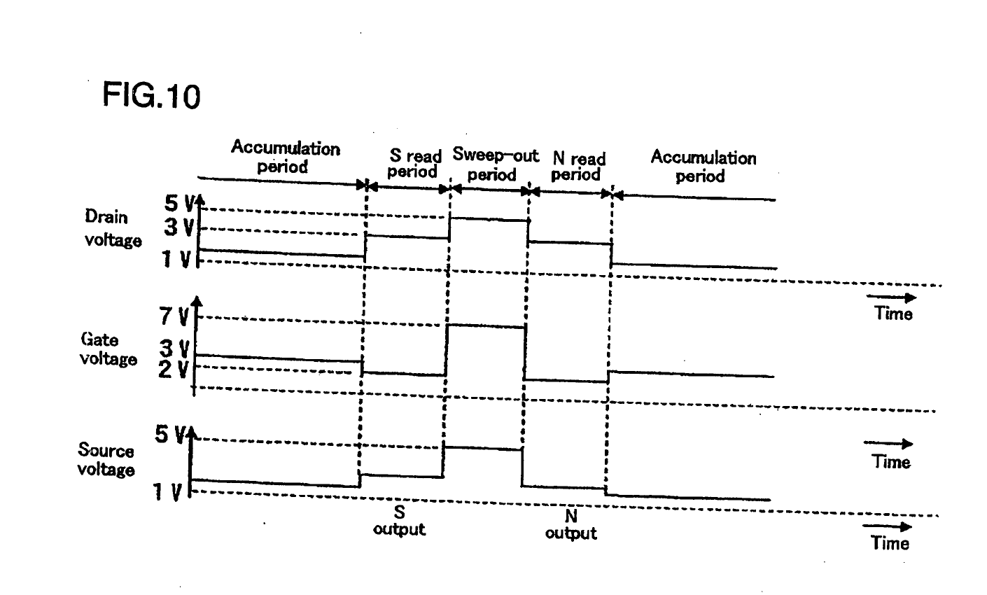

In an accumulation period, like in the solid-state imaging device shown in FIG. 10, the drain region 17 and the source region 21 of the optical signal detection MOS transistor 12 are each supplied with a voltage of 1 V. The gate electrodes (transfer gates) 19a and 19b of the optical signal transfer MOS transistors 13a and 13b, and the gate electrode (detection gate) 23 of the optical signal detection MOS transistor 12 are each supplied with a voltage of about 3 V. In the accumulation period, holes as optical signal carriers are generated in the P-type well regions 18a and 18b in an electrically floating state, by the light receiving diodes 11a and 11b being illuminated with light.

(Sweep-Out Period)

Next in a sweep-out period, the drain region 17 and the source region 21 are each supplied with a voltage of 4 V, and the transfer gates 19a and 19b and the detection gate 23 are each supplied with a high voltage of 6 V. With such settings, all the charges accumulated in the hole pocket region 22 are swept out toward the P-type substrate 14.

In the N-type well region 16, regions of the light receiving diodes 11a and 11b below the P-type well regions 18a and 18b are formed sufficiently deeper than a region below the hole pocket region 22. Therefore, the signal charges are suppressed from being swept out from the P-type well regions 18a and 18b toward the P-type substrate 14 in the sweep-out period.

(N Read Period)

In a noise read period (N read period), the source region 21 is connected to a constant current source. A source follower circuit is formed including the drain region 17, the gate electrode 23 and the source region 21. The drain region 17 is supplied with a voltage of 3 V, and the gate electrode 23 is supplied with a voltage of about 2 V. With such settings, the optical signal detection MOS transistor 12 is operated in a saturated state. Thus, a signal in the state where hole pocket region 22 has no optical signal (no holes) accumulated therein is read as a noise (N output).

In the N read period, the transfer gates 19a and 19b are each supplied with a voltage of about 3 V. The P-type well regions 18a and 18b in an electrically floating state are not electrically connected to the P-type well region 20. Therefore, the optical signals (signal charges) accumulated in the P-type well regions 18a and 18b stay therein and are electrically isolated from the hole pocket region 22 provided in the P-type well region 20.

(Transfer Period)

In a transfer period, the voltage applied to the transfer gate 19a becomes 0 V. Thus, the P-type well region 18a is electrically connected to the P-type well region 20. The voltage applied to the detection gate 23 also becomes 0 V. Thus, the potential of the hole pocket region 22 is decreased. With such settings, in an S1 transfer period, an optical signal S1 generated in the first pixel portion is transferred via the optical signal transfer MOS transistor 13a to the P-type well region 18a, then to the P-type well region 20, and to the hole pocket region 22.

(S Read Period)

In an S read period (signal read period), the source region 21 is connected to a constant current source. A source follower circuit is formed including the drain region 17, the gate electrode 23 and the source region 21. The drain region 17 is supplied with a voltage of 3 V, and the gate electrode 23 is supplied with a voltage of about 2 V. With such settings, the optical signal detection MOS transistor 12 is operated in a saturated state. Thus, in the S1 read period, the potential of the source region 21 is changed in accordance with the amount of the signal charges transferred from the light receiving diode 11a and accumulated in the hole pocket region 22, and the potential of the source region 21 is read as an S1 signal.

In the S read period, the transfer gates 19a and 19b are each supplied with a voltage of about 3 V. The P-type well regions 18a and 18b in an electrically floating state are not electrically connected to the P-type well region 20. Therefore, the optical signals (signal charges) accumulated in the P-type well regions 18a and 18b stay therein and are electrically isolated from the hole pocket region 22 provided in the P-type well region 20.

A difference between the signal S1 which is read in the S1 read period and the noise (signal N) which is read in the N read period is output through a differential amplification circuit, a clamp circuit or the like. In this manner, the influence of variance of offsets of the optical signal detection MOS transistors 12 is reduced.

While the image signal is read from the first pixel portion, the voltage of the transfer gate 19b becomes as high as 3 V or greater in the second pixel portion. Therefore, the optical signal obtained by opto-electric conversion in the P-type well region 18b in an electrically floating state stays in the P-type well region 18b.

After one horizontal line period, an image signal is read from the second pixel portion in substantially the same manner as in the first pixel portion. The operation of the second pixel portion is the same as that of the first pixel portion described above regarding the accumulation period to the S1 read period, except for the following. In the second pixel portion, the transfer gate 19b is used instead of the transfer gate 19a, the P-type well region 18b is used instead of the P-type well region 18a, and an S2 output is obtained instead of the S1 output.

A difference between the signal S2 which is read in the S2 signal read period and the noise (signal N) which is read in the N read period is output through a differential amplification circuit, a clamp circuit or the like.

As described above, the solid-state imaging device 100 in the first example requires two optical signal transfer MOS transistors 13a and 13b in the two pixel portions. However, the optical signal detection MOS transistor 12 having a large area can be shared by the two pixel portions. The areas of the light receiving diodes 11a and 11b can be made larger by that area, on a therefore the sensitivity of the solid-state imaging device 100 can be significantly improved.

In the solid-state imaging device 100 in the first example, the light receiving diodes 11a and 11b are located symmetrically on both sides of the optical signal detection MOS transistor 12. Therefore, the potential profile below the ring-shaped gate electrode 23 is more unlikely to be imbalanced between both sides of the optical signal detection MOS transistor 12, as compared to the conventional MOS-type image sensor. As a result, the linearity between the signal output and the optical signal generated by the light receiving diodes can be guaranteed.

In the solid-state imaging device 100 in the first example, the signal (S) is read after the noise (signal N) is read. Therefore, it is not necessary to completely deplete the hole pocket region 22 by completely sweeping out the optical signal components in the hole pocket region 22 toward the P-type substrate 14.

In the conventional MOS-type image sensor shown in FIG. 10, the noise (signal N) is read after the signal S is read. Therefore, the noise (signal N), which has the offset level corresponding to the current signal S, is read one frame before. In order to allow the noise (signal N), which is read after the signal S is read, to have the offset level, the signal charges in the hole pocket 22 need to be completely swept out toward the P-type substrate 14. The reason is that unless the signal charges in the hole pocket 22 are completely swept out to the P-type substrate 14, noise is generated by an incomplete reset operation.

By contrast, in the solid-state imaging device 100 in the first example of the present invention, the noise (signal N) is read immediately before the signal S is read. Therefore, the difference between the level of the signal (S) and the level of the noise (signal N) can be obtained. It is sufficient that the hole pocket region 22 has a space for accepting a sufficient amount of signal charges, before the signal charges corresponding to the signal S, flows into the hole pocket region 22. The potential of the source region 21 can have the offset level even when some residual charges stay in the hole pocket region 22. Accordingly, a very high voltage as required by the conventional MOS-type image sensor is not required in the sweep-out period. In the first example, the drain region 17, the detection gate 23 and the source region 21 are each applied with a voltage which is lower by about 1 V than that in the conventional MOS-type image sensor.

The general structure of the transfer gate used in the first example is disclosed in, for example, FIGS. 10 and 11 of Japanese Laid-Open Publication No. 2002-134729. In a solid-state imaging device disclosed in this publication, a transfer gate is provided between a light receiving area and an optical signal detection transistor via a gate insulating layer. The potential of the connection area is adjusted by the voltage applied to the transfer gate to act as a barrier against the generated signal charges corresponding to the received light. With such an adjustment, the flow of the signal charges corresponding to the received light from the light receiving area toward the carrier pocket region of the optical signal detection transistor can be controlled when necessary.

In the first example, the transfer gates are respectively provided at a center between one optical signal detection transistor and a plurality of light receiving diodes (two in FIG. 1). Thus, the flow of signal charges from each light receiving diode toward the hole pocket region is controlled. More specifically, the plurality of paths from the light receiving diodes toward the hole pocket region are selectively switched. With such a control, the optical signal detection MOS transistor 12 having a large area (insulating layer type field effect transistor) can be shared by a plurality of pixel portions (a plurality of light receiving regions). Therefore, the area of the light receiving diodes can be increased while the area of the pixel portions is kept the same. As a result, the sensitivity of the MOS-type image sensor can be significantly improved, an image signal with less noise can be read from the pixel portions (signal read), and the operating voltage can be reduced.

In the first example, the light receiving diodes 11a and 11b are located in an upper part and a lower part of FIG. 1 symmetrically with the optical signal detection MOS transistor 12 interposed therebetween. The present invention is not limited to such a structure. The light receiving diodes 11a and 11b may be located in a left part and a right part of FIG. 1, in an upper left part and a lower right part of FIG. 1, or in an upper right part and a lower left part of FIG. 1, symmetrically with the optical signal detection MOS transistor 12 interposed therebetween. Alternatively, as described in a second example of the present invention below, four light receiving diodes may be provided symmetrically around the optical signal detection MOS transistor 12. Three or five or more light receiving diodes may be provided symmetrically around the optical signal detection MOS transistor 12. In such cases, the light receiving diodes may be provided radially with the optical signal detection MOS transistor 12 at the center.

### EXAMPLE 2

In the first example, one optical signal detection MOS transistor is shared by two pixel portions (more specifically, two light receiving regions) in each pixel block. In the second example, one optical signal detection MOS transistor is shared by four pixel portions (more specifically, four light receiving regions).

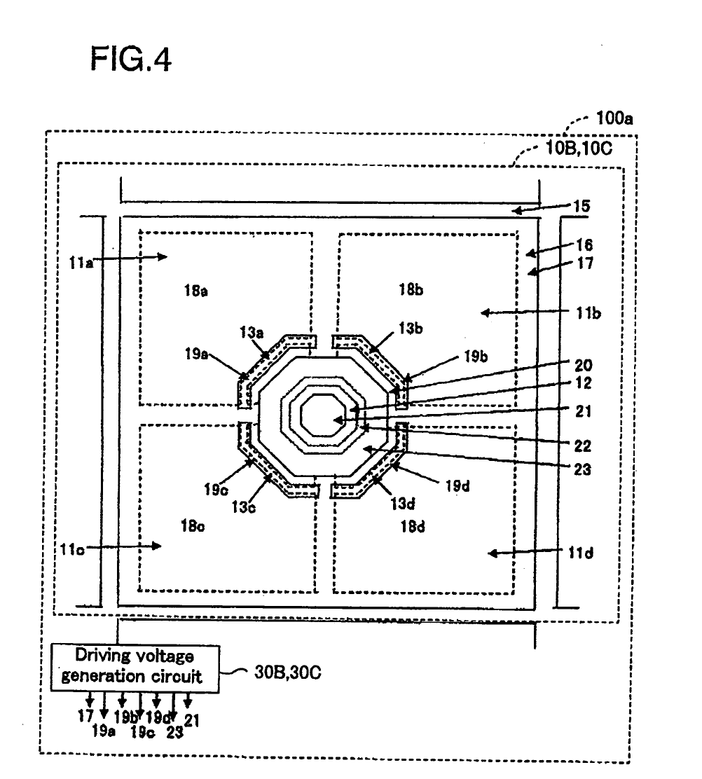

FIG. 4 shows a solid-state imaging device 100a according to the second example of the present invention. The solid-state imaging device 100a is a MOS-type image sensor including at least one pixel block 10B and a driving voltage generation circuit 30B.

FIG. 4 is a plan view of one pixel block 10B of the MOS-type image sensor 100 in the second example of the present invention. Identical elements as described above with reference to FIGS. 1 and 2 bear identical reference numerals thereto and a detailed description thereof will be omitted.

As shown in FIG. 4, the pixel block 10B includes four pixel portions (light receiving regions) in an upper right part, an upper left part, a lower right part and a lower left part in FIG. 4. One optical signal detection MOS transistor 12 is provided at a center of the pixel block 10B and surrounded by light receiving diodes (light receiving regions) 11a through 11d respectively corresponding to the four pixel portions. Optical signal transfer MOS transistors 13a through 13d (optical signal transfer control sections) are respectively provided between the light receiving diodes 11a through 11d and the optical signal detection MOS transistor 12.

The light receiving diodes 11a through 11d respectively include P-type well regions 18a through 18d in an electrically floating state. On paths including the drain region 17, P-type well regions 18a through 18d, the N-type well region 16, the P-type well region 20 and the source region 211 gate electrodes 19a through 19d (transfer gates) of the optical signal transfer MOS transistors 13a through 13d are respectively provided with a gate insulating layer interposed therebetween. Except for the above-described elements, the MOS-type image sensor (solid-state imaging device) 100a shown in FIG. 4 has substantially the same structure as that of the solid-state imaging device 100a shown in FIG. 1. Substantially the same parts of the structure will not be described here.

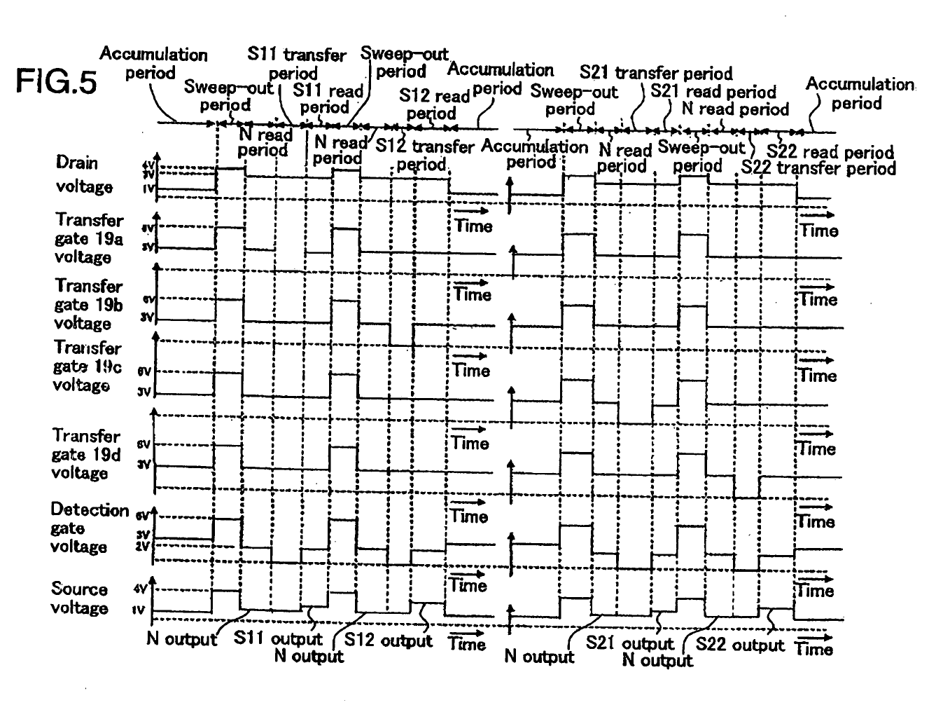

The solid-state imaging device 100a shown in FIG. 4 includes a driving voltage generation circuit 30B for controlling an imaging operation of the pixel block 10B. The driving voltage generation circuit 30D outputs driving voltages as shown in FIG. 5 to the drain region 17, the transfer gates 19a through 19d, the detection gate 23, and the source region 21 at a prescribed timing.

FIG. 5 is a timing diagram illustrating signal waveforms regarding an operation of the solid-state imaging device 100a shown in FIG. 4. FIG. 5 shows the signal waveforms in the drain region 17, the transfer gates 19a through 19d, the detection gate 23 and the source region 21.

The basic operation of the MOS-type image sensor 100a shown in FIG. 4 is substantially the same as that of the MOS-type image sensor 100 shown in FIG. 1. The MOS-type image sensor shown 100a in FIG. 4, which includes two more pixel portions to as compared to the MOS-type image sensor 100 shown in FIG. 1, needs to be operated faster accordingly. For example, for operating the two upper pixel portions, the following operations are necessary. A sweep-out operation, an N read operation, an S11 (signal S of the upper left pixel portion) transfer operation, and an S11 read operation are performed; and then, a sweep-out operation, an N read operation, an S12 (signal S of the upper right pixel portion) transfer operation, and an S12 read operation are performed. One horizontal line period later, the two lower pixel portions are operated as follows. A sweep-out operation, an N read operation, an S21 (signal S of the lower left pixel portion) transfer operation, and an S21 read operation are performed; and then, a sweep-out operation, an N read operation, an S22 (signal S of the lower right pixel portion) transfer operation, and an S22 read operation are performed. Therefore, for performing the operations shown in FIG. 5, the MOS-type image sensor (solid-state imaging device) 100a needs to be operated about twice as fast as for performing the operations shown in FIG. 3.

As a result, a difference between the signal S which is read in each S read period (S11, S12, S21 or S22) and the noise (signal N) which is read in the N read period is output via a differential amplification circuit, a clamp circuit or the like. In this manner, the influence of variance of offsets of the optical signal detection MOS transistors 12 of the pixel areas 10 is reduced.

As described above, the MOS-type image sensor 100a in the second example requires four optical signal transfer MOS transistors 13a through 13d in the four pixel portions, and needs to be operated faster. However, the optical signal detection MOS transistor 12 having a large area can be shared by the four pixel portions. The areas of the light receiving diodes 11a through 11d can be made larger by that area, and therefore the sensitivity of the MOS-type image sensor can be significantly improved.

In the MOS-type image sensor 100a in the second example, the light receiving diodes 11a through 11d are located symmetrically around the optical signal detection MOS transistor 12. Therefore, the potential profile below the ring-shaped gate electrode 23 is more unlikely to be imbalanced between both sides of the optical signal detection MOS transistor 12, as compared to the conventional MOS-type image sensor. As a result, the linearity between the signal output and the optical signal generated by the light receiving diodes can be guaranteed.

In the MOS-type image sensor 100a in the second example, the signal (S) is read after the noise (signal N) is read. Therefore, it is not necessary to completely deplete the hole pocket region 22 by completely sweeping out the optical signal components in the hole pocket region 22 toward the P-type substrate 14. Accordingly, a very high voltage as required by the conventional MOS-type image sensor is not required in the sweep-out period. In the second example, the drain region 17, the detection gate 23 and the source region 21 are each applied with a voltage which is lower by about 1 V than that in the conventional MOS-type image sensor. Thus, the voltage required for the sweep-out period can be reduced.

### EXAMPLE 3

In a third example of the present invention, the N read operation and the sweep-out operation for the signals S12 and S22 are omitted, so that the speed of the other operations of the pixel blocks (FIG. 4) is decreased.

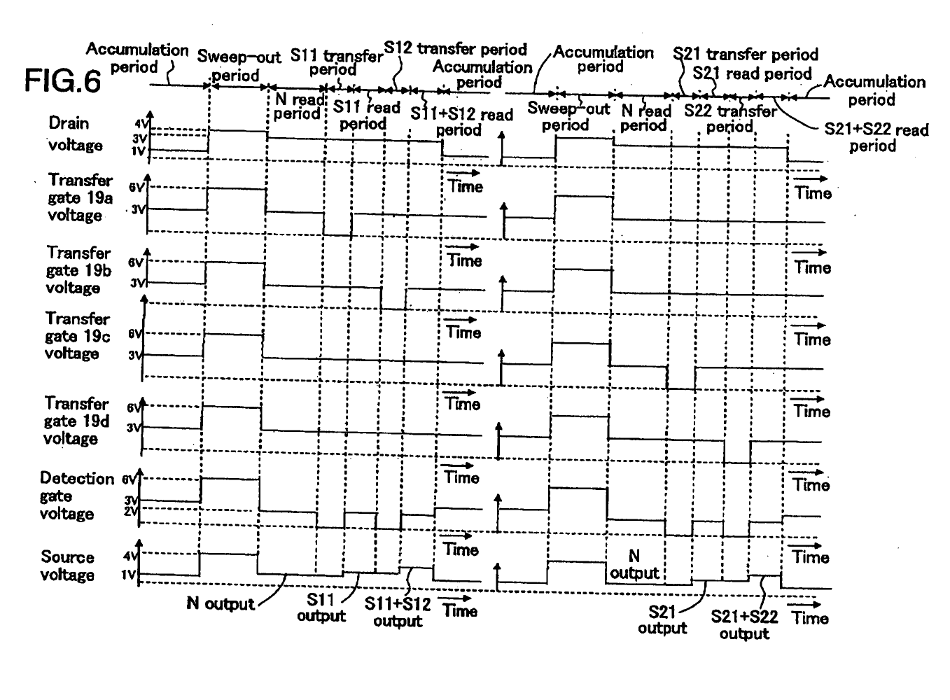

FIG. 4 is also used for describing a MOS-type image sensor according to the third example of the present invention. In the third example, the pixel block is represented by 10C, and the MOS-type image sensor includes a driving voltage generation circuit 30C. The driving voltage generation circuit 30C outputs driving voltages as shown in FIG. 6 to the drain region 17, the transfer gates 19a through 19d, the detection gate 23, and the source region 21 at a prescribed timing.

FIG. 6 is a timing diagram illustrating signal waveforms regarding an operation of the MOS-type image sensor in the third example. FIG. 6 shows the signal waveforms in the drain region 17, the transfer gates 19a through 19d, the detection gate 23 and the source region 21 in the MOS-type image sensor shown in FIG. 4.

By a method for driving the MOS-type image sensor shown in FIG. 6, an image signal of each of the upper left pixel portion and the lower left pixel portion is obtained by a difference between the signal S (S11 or S21) which is read in the respective S read period and the noise (signal N) which is read in the N read period. An image signal of each of the upper right pixel portion and the lower right pixel portion is obtained by a difference between the signal S (S12 or S22) which is read in the respective S read period and the signal S which is read in the s read period immediately before (S11 or S21).

The driving method in the third example (FIG. 6) allows the MOS-type image device (solid-state imaging device) to be operated at a lower speed than the driving method shown in FIG. 5.

### EXAMPLE 4

In a fourth example of the present invention, the channel stop region 15 is omitted in order to increase the area of the light receiving diodes.

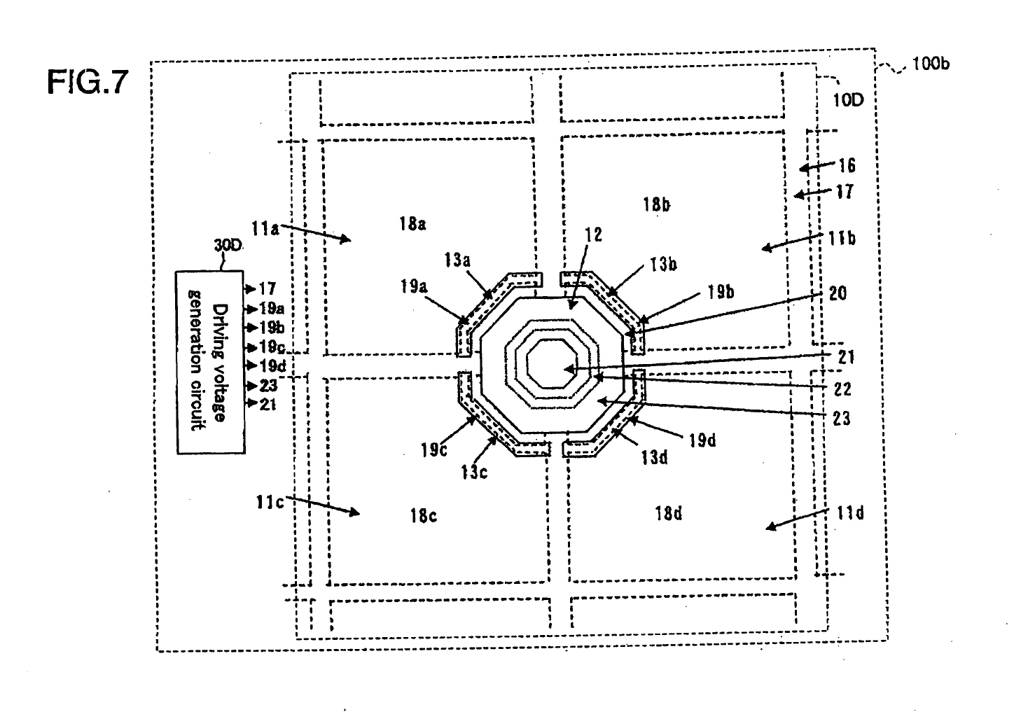

FIG. 7 shows a solid-state imaging device 100b according to the fourth example of the present invention. The solid-state imaging device 100b is a MOS-type image sensor including at least one pixel blocks 10D and a driving voltage generation circuit 30D.

As shown in FIG. 7, the MOS-type image sensor 100b does not include the channel stop region 15 for separating two adjacent pixel blocks 10D. The drain region 17 and the N-type well region 16 are common to the all the pixel portions in one pixel block 10D. Except for this, the MOS-typo image 100b shown in FIG. 7 have substantially the same structure as that of the MOS-type image sensor 100a in the second example (FIG. 4). Substantially the same parts of the structure will not be described here.

The structure shown in FIG. 7 is realized utilizing the phenomenon that as long as the transfer gate voltage is low (for example, 0 V), the signal charges accumulated in the light receiving diodes are maintained even though the drain region 17, the source region 21 and the gate electrode (detection gate) 23 are each supplied with a high voltage in the sweep-out period.

The solid-state imaging device 100b shown in FIG. 7 includes a driving voltage generation circuit 30D for controlling an imaging operation of the pixel block 10D. The driving voltage generation circuit 30D outputs driving voltages as shown in FIG. 5 or 6 to the drain region 17, the transfer gates 19a through 19d, the detection gate 23, and the source region 21 at a prescribed timing.

In the fourth example, four light receiving diodes 11a through 11d are provided for one optical signal detection MOS transistor 12 as shown in FIG. 4; and in addition, the channel stop region 15 is omitted. Owing to such a structure, the area of the light receiving diodes can be further increased, and thus the sensitivity of the MOS-type image sensor 100b can be improved.

In the above-described examples, the optical signal detection MOS transistor 12 is surrounded by the plurality of light receiving diodes and provided at the center of each of the pixel blocks. A plurality of optical signal transfer transistors are provided between the optical signal detection MOS transistor 12 and the plurality of light receiving diodes. A flow of the signal charges from each light receiving diode toward the hole pocket region 22 is controlled by the corresponding optical signal transfer transistor. Owing to such a structure, the area occupied by the light receiving diodes is enlarged, and thus the light detection sensitivity can be improved. In addition, the relationship between the optical signal generated by each light receiving diode and the output signal from the solid-state imaging device can be made linear. According to the present invention, the level of the driving voltage which is required in the sweep-out period can be reduced.

According to the present invention, one optical signal detection transistor which is common to a plurality of unit pixel sections is provided. This increases the area occupied by the light receiving diodes, and significantly improves the light detection sensitivity.

An optical signal detection transistor is surrounded by the plurality of light receiving diodes and provided at the center of each pixel block. Therefore, the potential profile below the ring-shaped gate electrode is unlikely to be imbalanced, and thus the reliability of the read signal can be improved.

Since the hole pocket region does not need to be completely depleted of signal charges in the sweep-out period by a very high voltage, the driving voltage can be reduced to save on power.

Various other modifications will be apparent to and can be readily made by those skilled in the art without departing from the scope and spirit of this invention. Accordingly, it is not intended that the scope of the claims appended hereto be limited to the description as set forth is herein, but rather that the claims be broadly construed.

What is claimed is:

1. A solid-state imaging device, comprising at least one pixel block, wherein:
the at least one pixel block includes:
a plurality of light receiving sections for generating charges by opto-electric conversion of incident light;
an optical signal detection section, provided commonly to the plurality of light receiving sections, for outputting a signal in accordance with the amount of charges generated by each of the plurality of light receiving sections; and
a charge transfer control section for controlling a flow of the generated charges to the optical signal detection section.

2. A solid-state imaging device according to claim 1, wherein the optical signal detection section is surrounded by the plurality of light receiving sections.

3. A solid-state imaging device according to claim 1, wherein the optical signal detection section is located at the center of each of the plurality of light receiving sections.

4. A solid-state imaging device according to claim 1, wherein the charge transfer control section includes a plurality of transistors respectively provided between the optical signal detection section and the plurality of light receiving sections.

5. A solid-state imaging device according to claim 1, wherein:
each of the plurality of light receiving sections is a light receiving diode; and
the optical signal detection section is an optical signal detection transistor including a charge accumulation region for accumulating the charges generated by each of the plurality of light receiving sections.

6. A solid-state imaging device according to claim 5, wherein each of the plurality of light receiving sections includes:
a first conductivity type well region; and
a second conductivity type impurity diffusion region provided on the first conductivity type well region.

7. A solid-state imaging device according to claim 5, wherein:
the optical signal detection section further includes a second conductivity type drain region, a second conductivity type source region, a gate electrode, and a channel region;
the charge accumulation region is provided in a first conductivity type first well region;
the charge accumulation region is located closer to the second conductivity type source region than to the second conductivity type drain region; and
the charge accumulation region has an impurity concentration which is higher than the impurity concentration of the first conductivity type first well region.

8. A solid-state imaging device according to claim 7, wherein:
the gate electrode is ring-shaped;
the second conductivity type source region is surrounded by the gate electrode;
the gate electrode is surrounded by the second conductivity type drain region; and
the charge accumulation region is ring-shaped and is provided so as to surround the second conductivity type source region.

9. A solid-state imaging device according to claim 7, wherein each of the plurality of light receiving sections includes:
a first conductivity type second well region; and
a second conductivity type impurity diffusion region provided on the first conductivity type second well region;
wherein the second conductivity type drain region is formed integrally with the second conductivity type impurity diffusion region.

10. A solid-state imaging device according to claim 7, comprising a plurality of pixel blocks, and the second conductivity type drain region is shared by the plurality of pixel blocks.

11. A method for driving a solid-state imaging device, which includes at least one pixel block wherein:
the at least one pixel block includes:
a plurality of light receiving sections for generating charges by opto-electric conversion of incident light;
an optical signal detection section, provided commonly to the plurality of light receiving sections, for outputting a signal in accordance with the amount of charges generated by each of the plurality of light receiving sections; and
a charge transfer control section for controlling a flow of the generated charges to the optical signal detection section; and
the optical signal detection section includes a charge accumulation region for accumulating the charges generated by each of the plurality of light receiving sections, a drain region, a source region, a gate electrode, and a channel region;
the method comprising:
a sweep-out step of sweeping out charges accumulated in the charge accumulation region;
a first reading step of reading a potential of the source region after the sweep-out step is performed;
a transfer step of selecting one of the plurality of light receiving sections and transferring the charges generated by the selected light receiving section to the charge accumulation region; and
a second reading step of reading a potential of the source region in accordance with the amount of charges accumulated in the charge accumulation region.

12. A method according to claim 11, further comprising the step of outputting an image signal indicating a difference between the potential which is read in the first reading step and the potential which is read in the second reading step.

13. A method according to claim 11, wherein the sweep-out step, the first reading step, the transfer stop and the second reading step are performed for each of the plurality of light receiving sections.

14. A method according to claim 11, wherein:
the plurality of light receiving sections include a first light receiving section and a second light receiving section; and
the transfer step when the second light receiving section is selected is performed after the second reading step performed when the first light receiving section is selected.

15. A method according to claim 14, further comprising the step of outputting an image signal indicating a difference between the potential, which is read in the second reading step performed when the first light receiving section is selected, and the potential, which is read in the second reading step performed when the second light receiving section is selected.

16. A method according to claim 11, wherein in the sweep-out step, the charge accumulation region is not completely depleted.
